(19) United States
(12) Patent Application Publication
(10) Pub. No.: US 2009/0220803 A1
(43) Pub. Date: Sep. 3, 2009

(54) FILM DEPOSITING APPARATUS, GAS BARRIER FILM, AND PROCESS FOR PRODUCING GAS BARRIER FILMS

(75) Inventor: Tatsuya FUJINAMI, Odawara-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/394,933

(22) Filed: Feb. 27, 2009

(30) Foreign Application Priority Data
Feb. 29, 2008 (JP) 2008-050316

(51) Int. Cl. B32B 18/00; B32B 9/00; C23C 16/54

(52) U.S. Cl. 428/446; 428/702; 118/720

(57) ABSTRACT

A film depositing apparatus comprises: a vacuum chamber; a rotatable drum that is provided within the chamber, that is longer than the substrate in a direction of its width perpendicular to the direction of transport of the substrate, and around which the substrate is wrapped in a specified surface region; a film depositing unit provided within the chamber and forming a film in a specified range of a surface of the substrate as it is wrapped around the drum; and a mask provided in a face-to-face relationship with the drum isolating a first region which is an area of the drum around which the substrate is not wrapped and a second region which is within a range of the substrate where the film is to be formed by the film depositing unit and which is most downstream in a direction in which the drum rotates.

The entire contents of a document cited in this specification are incorporated herein by reference.

### BACKGROUND OF THE INVENTION

The present invention relates to a film depositing apparatus that forms a film on a surface of an elongated substrate in vacuum by a vapor-phase deposition technique, as well as a gas barrier film, and a process for producing gas barrier films. In particular, the present invention relates to a film depositing apparatus that has no need to open the system to the atmosphere for cleaning purposes during film formation on an elongated substrate but which can perform continuous film formation at high degree of capacity utilization and yet can form films of satisfactory quality; the present invention also relates to a gas barrier film, and a process for producing gas barrier films.

While various types of apparatus are known to be capable of continuous film deposition on an elongated substrate (a web of substrate) in a vacuum-filled chamber by plasma-enhanced CVD, an exemplary system uses a drum connected to the ground and an electrode positioned in a face-to-face relationship with the drum and connected to a radio-frequency power source.

In this type of film depositing apparatus, the substrate is wrapped around a specified area of the drum, which is then rotated to thereby transport the substrate in a longitudinal direction as it is in registry with a specified film depositing position, with a radio-frequency voltage being applied between the drum and the electrode to form an electric field while, at the same time, a feed gas for film deposition as well as argon gas and the like are introduced between the drum and the electrode, whereby a film is deposited on the surface of the substrate by plasma-enhanced CVD.

A problem with this film depositing apparatus is that not only the substrate but also the two end portions of the drum around which the substrate is not wrapped are contacted by the plasma and the feed gas and that therefore the reaction product formed during film deposition will unavoidably adhere to both end portions of the drum. As continuous film deposition proceeds on the elongated substrate, the reaction product adhering to both end portions of the drum will accumulate and is eventually dislodged as particles that will deteriorate the quality of the film being formed, hence, the quality of the final product.

To deal with this problem, the reaction product adhering to the drum is removed after the film depositing apparatus has been operated for a specified period of time. To remove the reaction product adhering to the drum, the film depositing apparatus must be shut down, opened to the atmosphere, and then evacuated again to a specified degree of vacuum, but this is a time-consuming procedure. Under the circumstances, there has been proposed a production apparatus that enables efficient removal of the reaction product adhering to the drum (see JP 2002-76394 A).

The apparatus described in JP 2002-76394 A is for producing thin-film semiconductors and it basically comprises a reaction compartment for forming a thin-film semiconductor on a surface of a film substrate, a gas supply means for supplying the reaction compartment with a feed gas as appropriate for the thin film to be formed, an evacuating means for discharging a gas as the pressure in the reaction compartment is controlled, a radio-frequency electrode provided within the reaction compartment in a face-to-face relationship with a side of the film substrate, a grounded electrode provided on the other side of the film substrate, a heater for heating the film substrate, and a transport means for transporting the film substrate from a delivery roll to a take-up roll as it passes between the grounded electrode and the radio-frequency electrode. This production apparatus is characterized in that the heater is in the form of a cylindrical heating roll, the grounded electrode is in the form of a cylindrical susceptor roll that is provided as a cylinder spaced from and concentric with the heating roll and which is provided between the delivery roll and the take-up roll to transport the film substrate, and the radio-frequency electrode is provided as a cylinder, partially cut away, that is in a face-to-face relationship with and concentric with the susceptor roll.

In the apparatus described in JP 2002-76394 A, the reaction product will adhere to the susceptor roll but since this susceptor roll which also works as a transport roll can be rotated, the reaction product can be removed in a comparatively wide space that provides ease in cleaning; hence, removal and clearing of the reaction product becomes an easy job to perform.

JP 2002-76394 A also describes a design in which the susceptor roll is adapted to be detachable from the heating roll and this provides greater ease in the job of removing and clearing the reaction product.

A further proposal with the film depositing apparatus is that an electrode smaller than the substrate wrapped around the drum be used in order to suppress the reaction product from adhering to the two end portions of the drum.

### SUMMARY OF THE INVETNION

In fact, however, the production apparatus described in JP 2002-76394 A has the need to be shut down and opened to the atmosphere before the lid of the chamber is opened to remove the reaction product adhering to the drum. After the reaction product adhering to the drum is removed, contamination must be prevented by getting rid of the gas within the chamber so that the chamber is again evacuated and supplied with the feed gas to effect film deposition. It takes time to evacuate the chamber. Thus, the production apparatus described in JP 2002-76394 A still involves the problem of taking much time in maintenance and suffering a drop in the degree of capacity utilization.

In addition, the film formed in those regions of the substrate that are in a face-to-face relationship with the end portions of the electrode in the direction of width perpendicular to the length of the substrate has a considerably different quality than the film formed in that region of the substrate that is in a face-to-face relationship with the central portion of the electrode. Hence, if an electrode smaller than the substrate is used in the film depositing apparatus, the film formed in the end portions of the substrate in the direction of its width does not have satisfactory quality. If the film does not have satisfactory quality, its end portions have to be cut off and the yield of film production drops.

During film deposition with the conventional film depositing apparatus, the substrate wrapped around the drum is transported in the longitudinal direction while the reaction product accumulates incrementally until a specified thickness of film is formed but again the film formed in those regions of the substrate that are in a face-to-face relationship with the end portions of the electrode in the longitudinal direction of the substrate has a different quality than the film formed in that region of the substrate that is in a face-to-face relationship with the central portion of the electrode. As a result, the film formed just after the start of film deposition has a different quality than the film formed toward the end of film deposition, introducing a difference in film quality in the direction of thickness. This causes a potential failure to obtain a homogeneous film in the direction of thickness.

An object, therefore, of the present invention is to solve the aforementioned problems of the prior art by providing a film depositing apparatus that has no need to open the system to the atmosphere for cleaning purposes during film formation on an elongated substrate but which can perform continuous film formation at high degree of capacity utilization and yet can form films of satisfactory quality.

Another object of the present invention is to provide a gas barrier film.

Yet another object of the present invention is to provide a process for producing gas barrier films.

A film depositing apparatus according to the invention comprises: a transport means that transports an elongated substrate in a specified transport path; a chamber; an evacuating unit that creates a specified degree of vacuum within the chamber; a rotatable drum that is provided within the chamber, that has an axis of rotation in a direction perpendicular to a direction of transport of the substrate, that is longer than the substrate in a direction of its width perpendicular to the direction of transport of the substrate, and around which the substrate transported by the transport means is wrapped in a specified surface region; a film depositing unit that is provided within the chamber and in which a film depositing substance is accumulated by a vapor-phase deposition technique to form a film in a specified range of a surface of the substrate as it is wrapped around the drum; and a mask provided in a face-to-face relationship with the drum isolating a first region which is an area of the drum around which the substrate is not wrapped and a second region which is within a range of the substrate where the film is to be formed by the film depositing unit and which is most downstream in a direction in which the drum rotates.

A gas barrier film according to the invention comprises: a substrate; and a gas barrier layer formed on a surface of the substrate by using such film depositing apparatus.

A process for producing a gas barrier film according to the invention comprises the steps of: providing a substrate having a surface; and forming a gas barrier layer on the surface of the substrate by using such film depositing apparatus.

### BRIEF DESCRIPTION OF THE DRAWINGS

FIG. 1 is a schematic diagram showing a film depositing apparatus according to an embodiment of the present invention.

FIG. 2A is a schematic side view showing a film depositing compartment in the film depositing apparatus shown in FIG. 1, and FIG. 2B is a schematic perspective view showing the relative positions of a drum, a mask and a film depositing electrode in the film depositing compartment.

FIG. 3 is a schematic diagram showing another example of the mask.

### DETAILED DESCRIPTION OF THE INVENTION

On the following pages, the film depositing apparatus, the gas barrier film, and the process for producing gas barrier films according to the present invention are described in detail with reference to the preferred embodiments shown in the accompanying drawings.

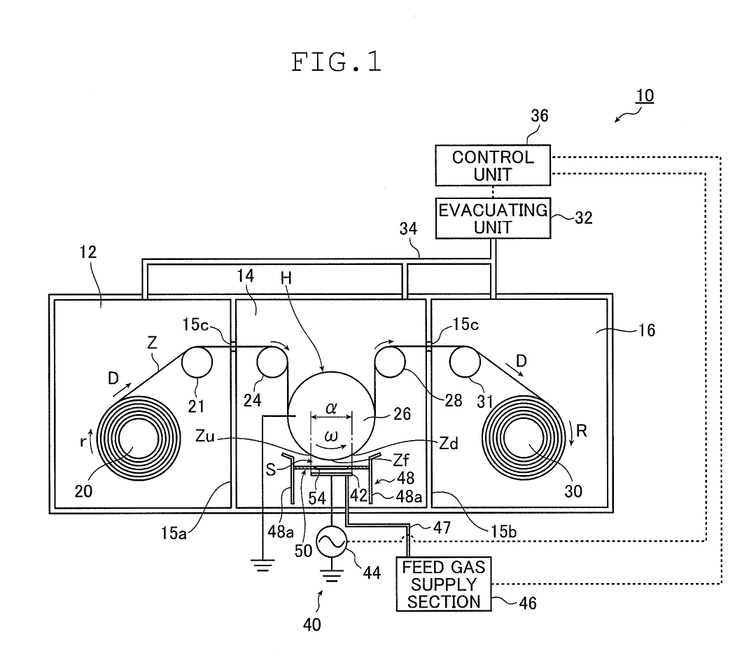

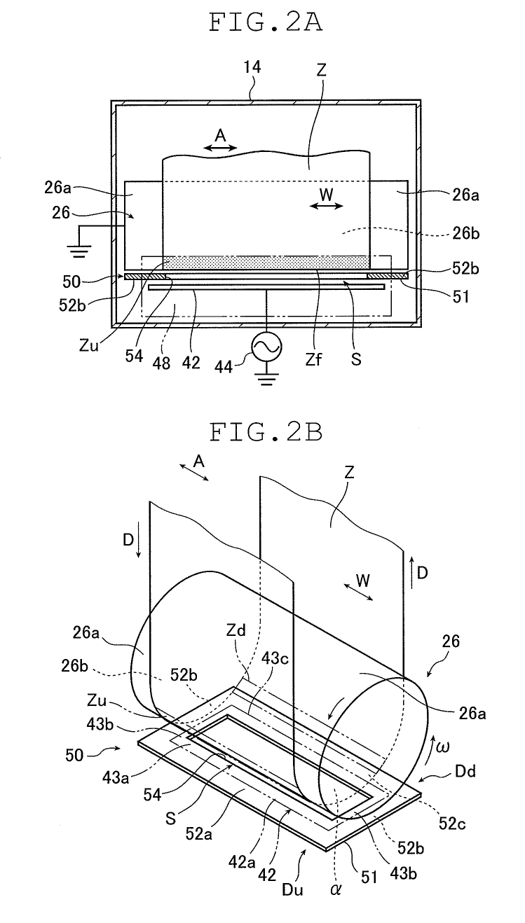

FIG. 1 is a schematic diagram showing a film depositing apparatus according to an embodiment of the present invention. FIG. 2A is a schematic side view showing a film depositing compartment in the film depositing apparatus shown in FIG. 1, and FIG. 2B is a schematic perspective view showing the relative positions of a drum 26, a mask 50 and a film depositing electrode 42 in the film depositing compartment. Note that FIG. 2A is a simplified presentation of the structure compared to FIG. 1 in that it shows only the drum 26, the film depositing electrode 42, a radio-frequency power source 44, a partition section 48 and the mask 50 while omitting the presentation of all other structural elements.

The film depositing apparatus generally indicated by 10 in FIG. 1 is a roll-to-roll type machine that forms a film with a specified function on the surface Zf of a substrate Z or on the surface of an organic layer if it is formed on the surface Zf of the substrate Z; the film depositing apparatus 10 is typically employed to produce functional films such as an optical film or a gas barrier film.

The film depositing apparatus 10 is an apparatus for continuously depositing a film on an elongated substrate Z (a web of substrate Z); it comprises basically a feed compartment 12 for feeding the elongated substrate Z, a film depositing compartment (chamber) 14 for forming a film on the elongated substrate Z, a take-up compartment 16 for winding up the elongated substrate Z after the film has been formed on it, an evacuating unit 32, and a control unit 36. The control unit 36 controls the actions of the individual elements of the film depositing apparatus 10.

In the film depositing apparatus 10, the feed compartment 12 and the film depositing compartment 14 are partitioned by a wall 15a whereas the film depositing compartment 14 and the take-up compartment 16 are partitioned by a wall 15b; a slit of opening 15c through which the substrate Z can pass is formed in each of the walls 15a and 15b.

In the film depositing apparatus 10, each of the feed compartment 12, the film depositing compartment 14 and the take-up compartment 16 is connected to the evacuating unit 32 via a piping system 34. The evacuating unit 32 creates a specified degree of vacuum in the interiors of the feed compartment 12, the film depositing compartment 14, and the take-up compartment 16.

To evacuate the feed compartment 12, the film depositing compartment 14 and the take-up compartment 16 to maintain a specified degree of vacuum, the evacuating unit 32 has vacuum pumps such as a dry pump and a turbo-molecular pump. Each of the feed compartment 12, the film depositing compartment 14 and the take-up compartment 16 is equipped with a pressure sensor (not shown) for measuring the internal pressure.

Note that the ultimate degree of vacuum that should be created in the feed compartment 12, the film depositing compartment 14 and the take-up compartment 16 by the evacuating unit 32 is not particularly limited and an adequate degree of vacuum suffices to be maintained in accordance with such factors as the method of film deposition to be performed. The evacuating unit 32 is controlled by the control unit 36.

The feed compartment 12 is a site for feeding the elongated substrate Z, where a substrate roll 20 and a guide roller 21 are provided.

The substrate roll 20 is for delivering the elongated substrate Z continuously and it typically has the substrate Z wound around it.

The substrate roll 20 is typically connected to a motor (not shown) as a drive source. By means of this motor, the substrate roll 20 is rotated in a direction r in which the substrate Z is rewound; in the embodiment under consideration, the substrate roll 20 is rotated clockwise to deliver the substrate Z continuously in FIG. 1.

The guide roller 21 is for guiding the substrate Z into the film depositing compartment 14 in a specified transport path. The guide roller 21 is composed of a known guide roller.

In the film depositing apparatus 10 of the embodiment under consideration, the guide roller 21 may be a drive roller or a follower roller. Alternatively, the guide roller 21 may be a roller that works as a tension roller that adjusts the tension that develops during the transport of the substrate Z.

In the film depositing apparatus of the present invention, the substrate Z is not particularly limited and all kinds of substrates can be employed as long as films can be formed by vapor-phase deposition techniques. Usable as the substrate Z are various resin films such as a PET film, or various metal sheets such as an aluminum sheet.

The take-up compartment 16 is a site where the substrate Z with a film having been formed on the surface Zf in the film depositing compartment 14 is wound up; in this take-up compartment 16, there are provided a take-up roll 30 and a guide roller 31.

The take-up roll 30 is a device by which the substrate Z on which a film has been deposited is wound up in a roll.

The take-up roll 30 is typically connected to a motor (not shown) as a drive source. By means of this motor, the take-up roll 30 is rotated to wind up the substrate Z after the film deposition step.

By means of the motor, the take-up roll 30 is rotated in a direction R in which the substrate Z is wound up; in the embodiment under consideration, the take-up roll 30 is rotated clockwise in FIG. 1, whereupon the substrate Z after the film deposition step is wound up continuously.

The guide roller 31 is similar to the aforementioned guide roller 21 in that the substrate Z being delivered from the film depositing compartment 14 is guided by this roller to the take-up roll 30 in a specified transport path. The guide roller 31 is composed of a known guide roller. Note that like the guide roller 21 in the feed compartment 12, the guide roller 31 may be a drive roller or a follower roller. Alternatively, the guide roller 31 may be a roller that works as a tension roller.

The film depositing compartment 14 functions as a vacuum chamber and it is a site where a film is continuously formed on the surface Zf of the substrate Z by a vapor-phase deposition technique, typically by plasma-enhanced CVD, as the substrate Z is being transported.

The film depositing compartment 14 is typically constructed by using materials such as stainless steel that are commonly employed in a variety of vacuum chambers.

In the film depositing compartment 14, there are provided two guide rollers 24 and 28, as well as a drum 26 and a film depositing unit 40.

The guide rollers 24 and 28 are spaced apart parallel to each other in a face-to-face relationship; they are also provided in such a way that their longitudinal axes cross at right angles to a direction D in which the substrate Z is transported.

The guide roller 24 is a device by which the substrate Z delivered from the guide roller 21 provided in the feed compartment 12 is transported to the drum 26. The guide roller 24 is rotatable, typically having an axis of rotation in direction A perpendicular to the direction D of transport of the substrate Z (this direction is hereinafter referred to as axial direction A (see FIG. 2A)), and its length in axial direction A is greater than the length in a width direction W perpendicular to the longitudinal direction of the substrate Z (the latter length is hereinafter referred to as the width of the substrate Z).

Note that the substrate roll 20 and the guide rollers 21 and 24 combine to constitute a first transport means according to the present invention.

The guide roller 28 is a device by which the substrate Z wrapped around the drum 26 is transported to the guide roller 31 provided in the take-up compartment 16. The guide roller 28 is rotatable, typically having an axis of rotation in axial direction A, and its length in axial direction A is greater than the width of the substrate Z.

Note that the guide rollers 28 and 31 as well as the take-up roll 30 combine to constitute a second transport means according to the present invention.

Except for the features just described above, the guide rollers 24 and 28 have the same structure as the guide roller 21 provided in the feed compartment 12, so they will not be described in detail.

The drum 26 is provided below the space H between the guide rollers 24 and 28. The drum 26 is so positioned that its longitudinal axis is parallel to those of the guide rollers 24 and 28. Also note that the drum 26 is electrically connected to the ground.

The drum 26 typically assumes a cylindrical shape and has an axis of rotation in axial direction A, about which it is capable of rotating in the direction of rotation ω. In addition, as shown in FIGS. 2A and 2B, the length of the drum 26 in axial direction A is greater than the width of the substrate Z. When the substrate Z is wrapped around the surface (peripheral surface) of the drum 26, with the center of the substrate Z in the direction of its width being in registry with the center of the drum 26 in its axial direction A, the end portions 26a on opposite sides of the drum 26 are regions around which the substrate Z is not wrapped (these regions are hereinafter referred to as the first region).

The drum 26, as it rotates with the substrate Z wrapped around its surface (peripheral surface), transports the substrate Z in the transport direction D while it is kept in registry with a specified film depositing position.

As shown in FIG. 1, the film depositing unit 40 is provided below the drum 26, and the drum 26, with the substrate Z being wrapped around it, rotates so that a film is formed on the surface Zf of the substrate Z as it is transported in the transport direction D.

The film depositing unit 40 is a device to form a film by a vapor-phase deposition technique, say, plasma-enhanced CVD and it has the film depositing electrode 42, the radio-frequency power source 44, a feed gas supply section 46, the partition section 48, and the mask 50. The control unit 36 controls the radio-frequency power source 44 and feed gas supply section 46 in the film depositing unit 40.

In the film depositing unit 40, the film depositing electrode 42 is provided in the lower part of the film depositing compartment 14 in a face-to-face relationship with, but separated by a specified clearance S from, a region 26b of the drum 26 around which the substrate Z is wrapped and with the mask 50 being inserted into the clearance S. In other words, the mask 50 is provided in the clearance S between the film depositing electrode 42 and the drum 26.

The film depositing electrode 42 is typically formed as a rectangular plate and it has a plurality of holes (not shown) formed at equal spacings in its major surface 42a. The film depositing electrode 42 is positioned with its major surface 42a being directed to the drum 26. The film depositing electrode 42 is of a type that is generally called a shower head electrode. The film depositing electrode 42 is longer than the size of the substrate Z in the direction of its width W as it is wrapped around the drum 26, so each of the end portions 43b of the film depositing electrode 42 reaches as far as the corresponding end portion 26a of the drum 26.

In addition, the film depositing electrode 42 is connected to the radio-frequency power source 44, which applies a radio-frequency voltage to the film depositing electrode 42.

The film depositing electrode 42 is in no way limited to a rectangular plate form and various other electrode configurations may be adopted as long as they are capable of film deposition by plasma-enhanced CVD; to give one example, it may consist of electrode segments that are arranged in axial direction A of the drum 26. Note here that in view of such factors as uniformity in the electric field and plasma that are to be applied to the substrate Z, the film depositing electrode 42 is preferably a shower head electrode of the rectangular plate form that is adopted in the embodiment under consideration.

It should also be noted that the film depositing electrode 42 and the radio-frequency power source 44 may optionally be connected to each other via a matching box in order to attain impedance matching.

In the embodiment under consideration, that range of the substrate Z that is wrapped around the drum 26 and over which a film is to be formed by the film depositing electrode 42, for example, the region of the film depositing electrode 42 as projected onto the drum 26, is a film deposition zone α. The two ends of the film deposition zone α are the most upstream portion Zu in the direction of rotation ω of the drum 26 (which is hereinafter referred to as the third region) and the most downstream portion Zd (the second region), respectively.

If the substrate Z is transported as it is wrapped around the drum 26, its position will change but even with such moving substrate Z, Zu or Zd may be referred to as the most upstream or downstream portion of the substrate Z, respectively, if it comes to be positioned in the most upstream portion Zu or the most downstream portion Zd in the direction of rotation ω of the drum 26.

The feed gas supply section 46 supplies, typically via the pipe 47, the film-forming feed gas into the clearance S through the plurality of through-holes formed in the film depositing electrode 42. The clearance S between the drum 26 and the film depositing electrode 42 serves as a space where plasma is to be generated.

In the embodiment under consideration, if a SiO₂ film is to be formed, the feed gas is a TEOS gas, with oxygen gas being used as an active species gas.

The feed gas supply section 46 may be chosen from a variety of gas introducing means that are employed in the plasma-enhanced CVD apparatus.

Also note that the feed gas supply section 46 may supply the clearance S not only with the feed gas but also with an inert gas such as argon or nitrogen gas, an active species gas such as oxygen gas, and various other gases used in plasma-enhanced CVD. In this case of introducing more than one species of gas, the respective gases may be mixed together in the same pipe and the mixture be passed through the plurality of holes in the film depositing electrode 42 to be supplied into the clearance S; alternatively, the respective gases may be supplied through different pipes and passed through the plurality of holes in the film depositing electrode 42 to be supplied into the clearance S.

The kinds of the feed gas, the inert gas and the active species gas, as well as the amounts in which they are introduced may be chosen and set as appropriate for various considerations including the kind of the film to be formed and the desired film deposition rate.

The partition section 48 demarcates the film depositing electrode 42 within the film depositing compartment 14.

The partition section 48 is typically composed of a pair of partition plates 48a, which are so placed as to hold the film depositing electrode 42 between them.

Each of the partition plates 48a is a member in plate form that extends in the longitudinal direction of the drum 26, with its end portion closer to the drum 26 being bent away from the film depositing electrode 42. The partition section 48 demarcates the clearance S, or the plasma generating space, within the film depositing compartment 14.

The mask 50 is a flat rectangular plate 52 having a rectangular opening 54 formed in it and it may typically be made of an insulator. An example of the insulator is ceramic such as alumina.

The mask 50 is placed so that the opening 54 is in a face-to-face relationship with the drum 26 with its longitudinal direction in alignment with axial direction A. The flat plate 52 is generally similar in external form to the film depositing electrode 42 but it is larger than the latter. The opening 54 is also generally similar in external form to the film depositing electrode 42 but it is smaller than the latter.

The mask 50 consists of three regions 52a, 52b and 52c that surround the opening 54.

The region 52a which extends in axial direction A of the flat plate 52 of the mask 50 is positioned on the upstream Du side in the transport direction D of the substrate Z, and it isolates the portion Zu of the substrate Z wrapped around the drum 26 which is most upstream in the film deposition zone α in the direction of rotation ω of the drum 26.

The regions 52b on opposite sides in axial direction A (width direction W) of the flat plate 52 of the mask 50 isolates those regions of the drum 26 around whose surface the substrate Z is not wrapped (the end portions 26a of the drum 26 (the first region)).

The region 52c which extends in axial direction A of the flat plate 52 of the mask 50 is positioned on the downstream Dd side in the transport direction D of the substrate Z, and it isolates the portion Zd of the substrate Z wrapped around the drum 26 which is most downstream in the film deposition zone α in the direction of rotation ω of the drum 26.

Now referring to the film depositing electrode 42, its end portion 43a which is upstream in the direction of rotation ω of the drum 26 is isolated by the region 52a of the mask 50, and its end portion 43c which is downstream in the direction of rotation ω of the drum 26 is isolated by the region 52c of the mask 50, and its end portions 43b on opposite sides in axial direction A are isolated by the regions 52b on opposite sides of the mask 50. Thus, only the central portion of the surface 42a of the film depositing electrode 42 will become exposed through the opening 54 but the end portions at the outer edge of the surface 42a are isolated by the mask 50.

As a result, during film deposition, the most upstream portion Zu and the most downstream portion Zd of the substrate Z are isolated by the mask 50, so that the reaction product which will form a film (the film depositing substance) is suppressed from accumulating at opposite ends of the film deposition zone α in the direction of rotation ω.

Those regions of the drum 26 around whose surface the substrate Z is not wrapped (the end portions 26a of the drum 26) are also isolated by the mask 50.

In consequence, during film deposition, the reaction product is blocked as it is generated by the plasma occurring in the neighborhoods of the outer edge (end portions 43a, 43b and 43c) of the film depositing electrode 42 whereas a film is formed by the reaction product as it is generated by the plasma occurring in the central portion of the surface 42a of the film depositing electrode 42. As a result, the film being formed in the end portions of the substrate Z in the direction of its width W is suppressed from becoming different in quality from the film being formed in the central portion and, at the same time, a homogeneous film can also be formed in the direction of rotation ω, whereby the film being formed is homogeneous in the direction of thickness.

Furthermore, even in those regions of the drum 26 around whose surface the substrate Z is not wrapped (the end portions 26a of the drum 26), the reaction product that is generated by the plasma during film deposition can be suppressed from adhering to the surface Zf of the substrate Z. As will be described later, this enables a film of good quality to be obtained with high productivity but without contaminating the interior of the film depositing compartment 14.

Note that the mask 50 is preferably roughened on the reverse side 51 which is away from the drum 26. By roughening the reverse side 51 of the mask 50, any reaction product that adheres to it during film deposition can do so with a greater force due to the anchor effect and it can be suppressed from dislodging to scatter about within the reaction compartment 14.

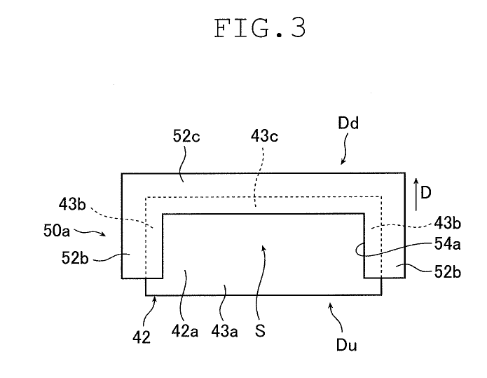

In the embodiment under discussion, the mask 50 is provided in the areas that correspond to the peripheral end portions 43a, 43b and 43c of the film depositing electrode 42 but this is not the sole case of the present invention and other versions are possible. For example, the mask may be modified as shown in FIG. 3, in which it is generally indicated by 50a and adapted to have a region 52c that isolates the most downstream portion Zd of the substrate Z in the direction of rotation ω of the drum 26, as well as two regions 52b that isolate the opposite end portions 26a of the drum 26 which are those regions of the drum 26 around which the substrate Z is not wrapped.

The mask 50a having this structure is capable of achieving the same effect as the mask 50 in the embodiment under discussion and the reaction product is suppressed from adhering to those regions of the drum 26 around which the substrate Z is not wrapped, whereby it becomes possible to obtain a film that is homogeneous in the direction of thickness.

If desired, the drum 26 may be equipped with a temperature adjusting section (not shown) for temperature adjustment and this temperature adjusting section is typically a heater provided in the center of the drum 26.

The drum 26 may also be equipped with another radio-frequency power source section (not shown) for applying a radio-frequency voltage. Since this additional radio-frequency power source section applies a bias voltage to the drum 26, a dense film can be obtained by the ion bombardment effect.

Note that the radio-frequency power source 44 and other radio-frequency power sources may be of any known type that is employed in film deposition by plasma-enhanced CVD. The maximum power output and other characteristics of the radio-frequency power source 44 and other radio-frequency power sources are not particularly limited and may be chosen and set as appropriate for various considerations including the kind of the film to be formed and the desired film deposition rate.

We next describe how the film depositing apparatus 10 according to the embodiment under consideration works.

In the specified path starting from the feed compartment 14 and passing through the film depositing compartment 14 to reach the take-up compartment 16, the elongated substrate Z is transported through the film depositing apparatus 10 from the feed compartment 12 down to the take-up compartment 16 while a film is formed on the substrate Z in the film depositing compartment 14.

In the film depositing apparatus 10, the elongated substrate Z that has been wound around the substrate roll 20 is unwound and transported into the film depositing compartment 14 via the guide roller 21. In the film depositing compartment 14, the substrate Z passes over the guide roller 24, the drum 26 and the guide roller 28 to be transported into the take-up compartment 16. In the take-up compartment 16, the elongated substrate Z passes over the guide roller 31 to be wound up by the take-up roll 30. After passing the elongated substrate Z through this transport path, a specified degree of vacuum is maintained in the interiors of the feed compartment 12, the film depositing compartment 14 and the take-up compartment 16 by means of the evacuating unit 32; then, in the film depositing unit 40, a radio-frequency voltage is applied from the radio-frequency power source 44 to the film depositing electrode 42 while, at the same time, the feed gas to form a film is supplied from the feed gas supply section 46 into the clearance S through the pipe 47.

When electromagnetic waves are radiated around the film depositing electrode 42, a plasma localized in the neighborhood of the film depositing electrode 42 is generated in the clearance S, whereupon the feed gas is excited and dissociated to yield a reaction product that serves to form a film. This reaction product accumulates to form a specified film on the surface Zf of the substrate Z.

On this occasion, the reaction product generated along the outer edge (end portions 43a, 43b and 43c) of the film depositing electrode 42 is blocked by the regions 52a, 52b and 52c of the mask 50 from reaching the surface Zf of the substrate Z, whereby the reaction product is suppressed from accumulating in the opposite end portions 26a of the drum 26, in the most upstream portion Zu of the substrate Z which is wrapped around the drum 26, and in its most downstream portion Zd (the second region).

On the other hand, the reaction product that was generated in the central part of the film depositing electrode 42 passes through the opening 54 in the mask 50 to accumulate on the surface Zf of the substrate Z until a specified thickness of film is formed.

Then, the substrate roll 20 around which the elongated substrate Z has been wound is rotated clockwise incrementally by means of the motor, whereupon the elongated substrate Z is delivered continuously and with the substrate Z being held on the drum 26 in the position where the plasma is being generated, the drum 26 is rotated at a specified speed to ensure that the film depositing unit 40 allows a film to be formed continuously on the surface Zf of the elongated substrate Z. As a result, the substrate Z having the specified film formed on its surface Zf, namely, a functional film, is produced. The function of the functional film produced depends on the properties or the type of the film formed on the substrate Z. The substrate Z having the specified film formed on its surface Zf passes over the guide rollers 28 and 31 so that the functional film, or the elongated substrate Z with the deposited film, is wound up by the take-up roll 30.

Described above is the way in which the substrate Z having the specified film formed on its surface Zf, namely, the functional film can be produced by the film depositing apparatus 10 according to the embodiment under consideration.

When a film is formed on the surface Zf of the elongated substrate Z by the film deposition method using the film depositing apparatus 10 in the embodiment under consideration, the mask 50 suppresses the reaction product from accumulating in those regions of the drum 26 around which the elongated substrate Z is not wrapped (i.e., the end portions 26a of the drum 26).

Hence, the film depositing compartment 14 need not be opened to the atmosphere to remove the reaction product (film depositing substance) that would otherwise be formed on the drum 26 and the time taken for maintenance can be reduced to ensure that the film depositing apparatus 10 can be operated continuously to increase the degree of capacity utilization.

As a further advantage, the reaction product (film depositing substance) is suppressed from accumulating in the end portions 26a of the drum 26, whereby the occurrence of particles and, hence, a drop in the film quality can be suppressed.

Thus, the film depositing apparatus 10 according to the embodiment under consideration is capable of continuous and consistent film deposition on the elongated substrate Z at high degree of capacity utilization and, what is more, it suppresses the occurrence of particles, thereby enabling films of satisfactory quality to be formed with high productivity.

Yet another advantage of the embodiment under consideration is that the mask 50 ensures that neither the reaction product generated near the end portion 43a of the film depositing electrode 42 which is on the upstream side Du in the transport direction D of the substrate Z nor the reaction product generated near the end portion 43c on the downstream side Dd will be used to form the film. Hence, the film can be formed without using any reaction product that might affect its quality and, as a result, a film can be formed that is homogeneous in the direction of thickness and which has good quality.

In addition, since the embodiment under consideration has no need to adjust the length of the film depositing electrode 42 to be smaller than the width of the substrate Z, no wastage as exemplified by the step of cutting off the end portions of the deposited film will occur and this contributes to a higher yield of production.

In the embodiment under consideration, the film to be deposited is not particularly limited and as long as vapor-phase deposition techniques are applicable, films having the required functions that depend on the functional films to be produced can appropriately be formed. The thickness of the film to be deposited also is not particularly limited and the required thickness may be determined as appropriate for the performance required by the functional film to be produced.

It should also be noted that the film to be deposited is not limited to a single-layer structure but may be composed of more than one layer. If a multi-layer film is to be formed, the individual layers may be the same or different from each other.

In the embodiment under consideration, if a gas barrier film (water vapor barrier film) is to be produced as the functional film, the film to be deposited on the substrate is an inorganic film such as a silicon nitride film, an aluminum oxide film, or a silicon oxide film.

If protective films for a variety of devices or apparatuses including display devices such as organic EL displays and liquid-crystal displays are to be produced as the functional film, the film to be deposited on the substrate is an inorganic film such as a silicon oxide film.

Further in addition, if the functional film produced is any of an anti-light reflective film, a light reflective film, and various other optical films for use in filters, the film to be deposited on the substrate is a film having the desired optical characteristics or a film comprising materials that exhibit the desired optical characteristics.

The functional film thus produced by the film depositing apparatus 10 according to the embodiment under consideration has a film of good quality formed on the substrate, so if it is a gas barrier film, it has good enough gas barrier property. What is more, in the case of producing functional films, films of good quality can be formed on the substrate with high efficiency and, further in addition, no wastage as exemplified by the step of cutting off the end portions of the deposited film will occur, contributing to a higher yield of production.

The foregoing description of the film depositing apparatus 10 of the embodiment under consideration has been made with reference to plasma-enhanced CVD but this is not the sole case of the present invention. As long as it is based on the vapor-phase deposition process, the film depositing unit according to the present invention may adopt a variety of physical vapor deposition (PVD), chemical vapor deposition (CVD), sputtering, evaporation, and ion plating techniques.

While the film depositing apparatus of the present invention has been described above in detail, the present invention is by no means limited to the foregoing embodiments and it should be understood that various improvements and modifications are possible without departing from the scope and spirit of the present invention.

What is claimed is:

1. A film depositing apparatus comprising:
a transport means that transports an elongated substrate in a specified transport path;
a chamber;
an evacuating unit that creates a specified degree of vacuum within the chamber;
a rotatable drum that is provided within the chamber, that has an axis of rotation in a direction perpendicular to a direction of transport of the substrate, that is longer than the substrate in a direction of its width perpendicular to the direction of transport of the substrate, and around which the substrate transported by the transport means is wrapped in a specified surface region;
a film depositing unit that is provided within the chamber and in which a film depositing substance is accumulated by a vapor-phase deposition technique to form a film in a specified range of a surface of the substrate as it is wrapped around the drum; and
a mask provided in a face-to-face relationship with the drum isolating a first region which is an area of the drum around which the substrate is not wrapped and a second region which is within a range of the substrate where the film is to be formed by the film depositing unit and which is most downstream in a direction in which the drum rotates.

2. The film depositing apparatus according to claim 1, wherein the mask further isolates a third region which is within the range of the substrate where the film is to be formed by the film depositing unit and which is most upstream in the direction in which the drum rotates.

3. The film depositing apparatus according to claim 1, wherein the film depositing unit comprises a film depositing electrode that is provided in a face-to-face relationship with the drum but separated therefrom by a specified clearance in which the mask is inserted, a radio-frequency power source section for applying a radio-frequency voltage to the film depositing electrode, and a feed gas supply section from which a feed gas for forming the film is supplied into the clearance.

4. The film depositing apparatus according to claim 1, wherein the mask is made up of an insulator.

5. The film depositing apparatus according to claim 1, wherein the mask has a planar first area that isolates the first region and a planar second area that isolates the second region, the first and the second area being roughened on a side away from a side that is in a face-to-face relationship with the drum.

6. The film depositing apparatus according to claim 5, wherein the mask further includes a planar third area that isolates a third region which is within the range of the substrate where the film is to be formed by the film depositing unit and which is most upstream in the direction in which the drum rotates, the third area being roughened on the side away from the side that is in a face-to-face relationship with the drum.

7. A gas barrier film comprising:
a substrate; and
a gas barrier layer formed on a surface of the substrate by using the film depositing apparatus according to claim 1.

8. A process for producing a gas barrier film comprising the steps of:
providing a substrate having a surface; and
forming a gas barrier layer on the surface of the substrate by using the film depositing apparatus according to claim 1.
